(19) United States
(12) Patent Application Publication
(10) Pub. No.: US 2016/0372212 A1
(43) Pub. Date: Dec. 22, 2016

(54) TEST APPARATUS, TEST METHOD AND METHOD OF MANUFACTURING MAGNETIC MEMORY

(71) Applicant: KABUSHIKI KAISHA TOSHIBA, Tokyo (JP)

(72) Inventor: Tatsuya KISHI, Seongnam-si (KR)

(73) Assignee: KABUSHIKI KAISHA TOSHIBA, Tokyo (JP)

(21) Appl. No.: 15/067,774

(22) Filed: Mar. 11, 2016

Related U.S. Application Data
(60) Provisional application No. 62/180,401, filed on Jun. 16, 2015.

(51) Int. Cl. G11C 29/44; G11C 11/16

(52) U.S. Cl. CPC G11C 29/44; G11C 11/1673; G11C 11/1675

(57) ABSTRACT

According to one embodiment, a test apparatus includes an interface portion to which a magnetic memory with a memory cell array is connected, the memory cell array including a center area and a peripheral area, the center area being located inside an edge of the memory cell array by a predetermined value, and a controller controlling a test of the magnetic memory. The controller is configured to execute the test for one of the peripheral area and the center area base on a kind of the test.

### CROSS-REFERENCE TO RELATED APPLICATIONS

This application claims the benefit of U.S. Provisional Application No. 62/180,401, filed Jun. 16, 2015, the entire contents of which are incorporated herein by reference.

### FIELD

Embodiments described herein relate generally to a test apparatus, a test method and a method of manufacturing a magnetic memory.

### BACKGROUND

In a magnetic memory with magnetoresistive elements, such as a spin-torque-transfer magnetic random access memory (STT-MRAM), the current necessary for magnetization inversion of the magnetoresistive elements is defined by the current density. That is, the magnetic memory has such scalability that the current necessary for magnetization inversion decreases as the size of the magnetoresistive elements decreases.

By virtue of this feature, such a magnetic memory is regarded as one of the major candidates for next-generation memories.

To put a magnetic memory with magnetoresistive elements into practical use, it is necessary to detect, by a test, a fail bit that does not satisfy the specifications, and to replace it with a pass bit that satisfies the specifications, using, for example, a redundancy technique, as in the case of a general semiconductor memory. However, there is a problem that the test method of such a magnetic memory requires time.

### BRIEF DESCRIPTION OF THE DRAWINGS

FIG. 1 is a block diagram showing an example of a test apparatus which tests a magnetic memory.

FIG. 2 is a perspective view showing a package as an example of the magnetic memory.

FIG. 3 and FIG. 4 are plan views showing examples of a layout of magnetoresistive elements of the memory cell array.

FIG. 5A and FIG. 5B are cross-sectional views seen along V-V of FIG. 3.

FIG. 6 is an illustration of a test method of a first embodiment.

FIG. 7A and FIG. 7B are graphs showing a relationship between distance Di from a target to an adjacent element and a stray magnetic field Hshifti applied from the adjacent element to the target.

FIG. 8 is a detailed view of case A of the test method shown in FIG. 6.

FIG. 9 is a detailed view of case B of the test method shown in FIG. 6.

FIG. 10 is a detailed view of case C of the test method shown in FIG. 6.

FIG. 11 is a detailed view of case D of the test method shown in FIG. 6.

FIG. 12 is a graph showing a test method of a second embodiment.

FIG. 13 is a detailed view of cases E and F of the test method shown in FIG. 12.

FIG. 14 is a flowchart showing a test method of a third embodiment.

FIG. 15, FIG. 16, FIG. 17 and FIG. 18 are plan views showing examples of a test area.

FIG. 19 is a flowchart showing a method of manufacturing a magnetic memory of a fourth embodiment.

FIG. 20 is a flowchart showing an example of a retention test.

FIG. 21 is a flowchart showing an example of a read disturb test.

FIG. 22 is a flowchart showing an example of a WER test.

FIG. 23, FIG. 24 and FIG. 25 are plan views showing a memory cell array of magnetoresistive elements of a fifth embodiment.

FIG. 26 is a plan view showing memory cells of an MRAM as an application example.

FIG. 27 is a cross-sectional view seen along XXVII-XXVII of FIG. 26.

FIG. 28 is a cross-sectional view seen along XXVIII-XXVIII of FIG. 26.

### DETAILED DESCRIPTION

In general, according to one embodiment, a test apparatus comprises: an interface portion to which a magnetic memory with a memory cell array is connected, the memory cell array including a center area and a peripheral area, the center area being located inside an edge of the memory cell array by a predetermined value; and a controller controlling a test of the magnetic memory. The controller is configured to execute the test for one of the peripheral area and the center area base on a kind of the test.

[Test Apparatus]

FIG. 1 shows an example of a test apparatus which tests a magnetic memory.

A tester 10 comprises a controller 11 and an interface portion 12. The controller 11 comprises a section for generating a test signal needed for a test to guarantee the operation of a magnetic memory, and a section for controlling the test. The magnetic memory 13 is connected to the controller 11 by the interface portion 12. For example, the interface portion 12 has a socket structure into which a magnetic memory can be fitted.

A test magnetic field generating portion 14 and a temperature control portion 15 can be omitted, but are hereinafter described because they are effective for reducing the test time.

The test magnetic field generating portion 14 generates a test magnetic field at least while the magnetic memory 13 is being tested by a test signal from the controller 11. For example, the test magnetic field generating portion 14 comprises a Helmholtz electromagnet. The test of the magnetic memory 13 can be accelerated and the test time can be reduced by generating the test magnetic field during the testing of the magnetic memory 13.

The test magnetic field generating portion 14 is provided outside the tester 10, but may be provided inside the tester 10. In addition, the test magnetic field generating portion 14 is driven by the controller 11 of the tester 10, but may be driven independently of the tester 10.

The temperature control portion 15 manages the temperature of the magnetic memory 13 at least while the magnetic memory 13 is being tested by a test signal from the controller 11. The temperature control portion 15 comprises, for example, a heater for producing heat, a sensor for detecting the temperature, etc. The test of the magnetic memory 13 can be accelerated and the test time can be reduced by producing heat during the testing of the magnetic memory 13.

The temperature control portion 15 is provided outside the tester 10, but may be provided inside the tester 10. In addition, the temperature control portion 15 is driven by the controller 11 of the tester 10, but may be driven independently of the tester 10.

The magnetic memory 13 is tested while applying a test magnetic field and/or heat to the magnetic memory 13.

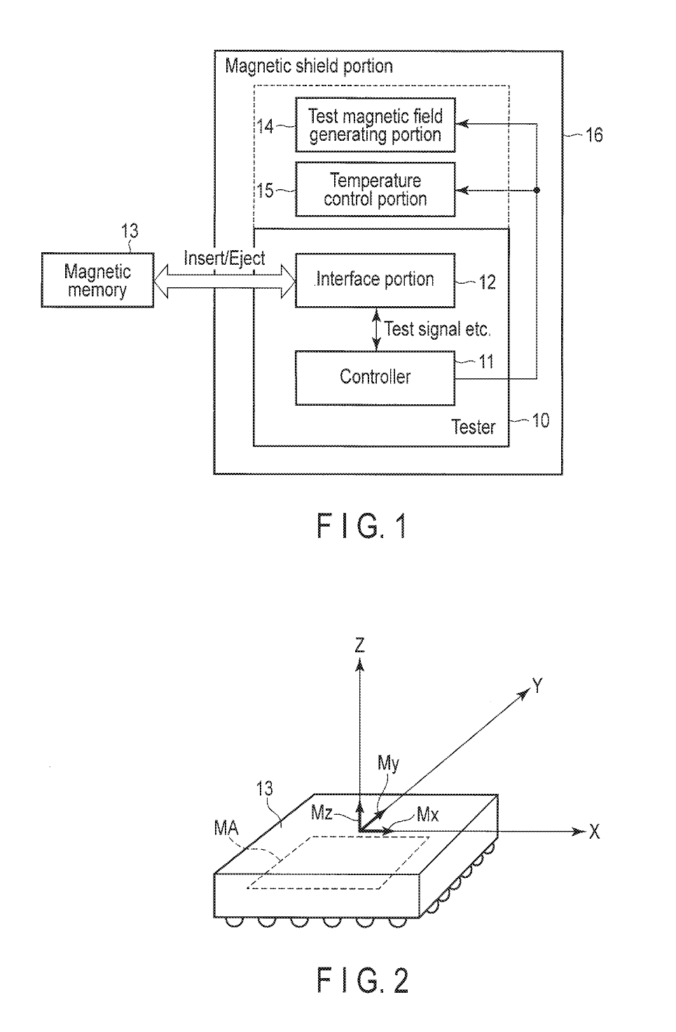

As shown in FIG. 2, the test magnetic field is an x-directional magnetic field Mx, a y-directional magnetic field My, or a z-directional magnetic field Mz with respect to, for example, the package of the magnetic memory 13. Alternatively, the test magnetic field may be a combination of these magnetic fields Mx, My and Mz.

For instance, the test magnetic field may be a combination of the x-directional magnetic field Mx and the y-directional magnetic field My, a combination of the x-directional magnetic field Mx and the z-directional magnetic field Mz, a combination of the y-directional magnetic field My and the z-directional magnetic field Mz, or a combination of the x-directional magnetic field Mx, the y-directional magnetic field My and the z-directional magnetic field Mz.

MA indicates a memory cell array in the magnetic memory 13. The memory cell array MA comprises magnetoresistive elements.

A magnetic shield portion 16 has a space shielded from an external magnetic field. The tester 10, the test magnetic field generating portion 14 and the temperature control portion 15 are provided in the space.

The magnetic shield portion 16 should preferably include Ni, Fe, Co, Ni—Fe alloy, Fe—Co alloy, Fe₂O₄ containing Ni, Mn or Zn, etc. To enhance the shielding effect against the external magnetic field, the magnetic shield portion 16 may be a housing thicker than 100 nm and thinner than 10 mm, and preferably has a thickness of 1 to 5 mm.

However, the magnetic shield portion 16 may be omitted. That is, the magnetic shield portion 16 is needed when a detailed test is executed to detect a critical defect, but the magnetic shield portion 16 is not needed, for example, when a rough test is executed to detect a general defect that does not include a critical one.

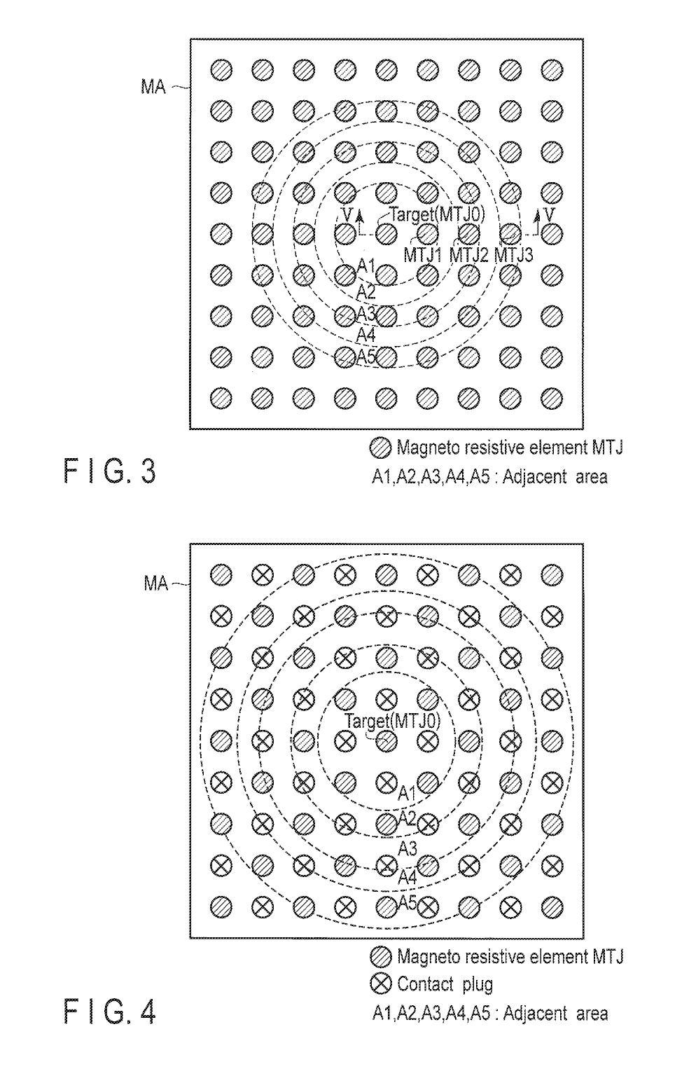

FIG. 3 and FIG. 4 show examples of a layout of the magnetoresistive elements in the memory cell array.

In the memory cell array MA, the magnetoresistive elements MTJ are systematically laid out. In the example of FIG. 3, the magnetoresistive elements MTJ are arrayed in a lattice pattern. In the example of FIG. 4, the magnetoresistive elements MTJ are arrayed like a houndstooth check.

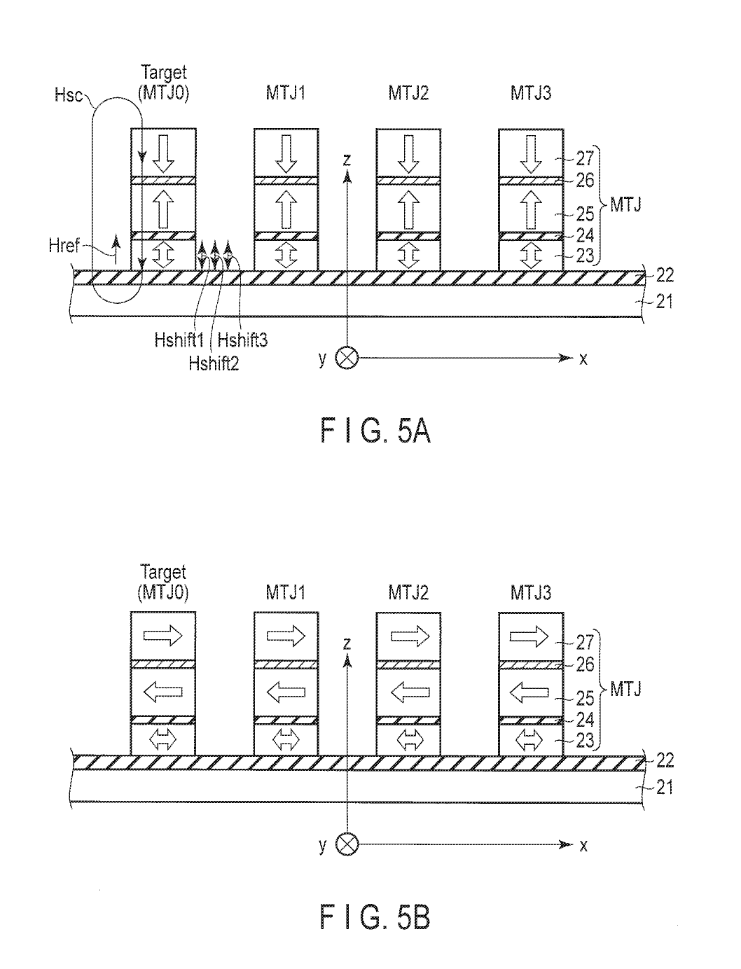

For example, as shown in FIG. 5A and FIG. 5B, the magnetoresistive elements MTJ are arrayed on an insulating layer 22 on a semiconductor substrate 21.

FIG. 5A and FIG. 5B correspond to a cross-section along V-V of FIG. 3.

For example, each magnetoresistive element MTJ has a stacked structure of a storage layer 23 having perpendicular and variable magnetization, a nonmagnetic insulating layer (tunnel barrier layer) 24, a reference layer 25 having perpendicular and invariable magnetization, a nonmagnetic conductive layer 26 and a shift canceling layer 27, as shown in FIG. 5A. It should be noted that the term “perpendicular” means being perpendicular to the upper surface of the semiconductor substrate 21.

For example, each magnetoresistive element MTJ may have a stacked structure of a storage layer 23 having in-plane and variable magnetization, a nonmagnetic insulating layer (tunnel barrier layer) 24, a reference layer 25 having in-plane and invariable magnetization, a nonmagnetic conductive layer 26 and a shift canceling layer 27, as shown in FIG. 5B. It should be noted that the term “in-plane” means being parallel to the upper surface of the semiconductor substrate 21.

It should also be noted that the invariable magnetization means that the direction of magnetization is not changed around the time of a write and the variable magnetization means that the direction of magnetization can be inverted around the time of a write. The write is a spin-transfer write which provides the magnetization of the storage layer with a spin torque by applying a spin injection current (spin-polarized electrons) to the magnetoresistive element MTJ.

In FIG. 5A and FIG. 5B, the reference layer 25 is provided above the storage layer 23. However, the reference layer 25 may be provided below the storage layer 23. The former is called a top pin type and the latter is called a bottom pin type.

The resistance of each magnetoresistive element MTJ is changed depending on the relative directions of magnetization of the storage layer 23 and the reference layer 25 by the magnetoresistive effect. For example, the resistance of each magnetoresistive element MTJ becomes low in a parallel state in which the direction of magnetization of the storage layer 23 is the same as that of the reference layer 25, and becomes high in an antiparallel state in which the direction of magnetization of the storage layer 23 is opposite to that of the reference layer 25.

The storage layer 23 and the reference layer 25 comprise, for example, CoFeB, MgFeO, FeB, lamination of them, etc. In the case of the magnetoresistive elements having vertical magnetization, the storage layer 23 and the reference layer 25 should preferably comprise TbCoFe having a perpendicular magnetic anisotropy, an artificial lattice in which Co and Pt are stacked, FePt regularized by Lₗₒ or the like. In this case, CoFeB or FeB may be provided as interface layers between the storage layer 23 and the nonmagnetic insulating layer 24 and between the nonmagnetic insulating layer 24 and the reference layer 25.

For example, In both of the top pin type and the bottom pin type, it is preferable that the storage layer 23 includes CoFeB or FeB, and the reference layer 25 includes CoPt, CoNi, or CoPd.

The nonmagnetic insulating layer 24 comprises, for example, MgO, AlO or the like. The nonmagnetic insulating layer 24 maybe a nitride of Al, Si, Be, Mg, Ca, Sr, Ba, Sc, Y, La, Zr, Hf or the like.

The shift canceling layer 27 is a magnetic layer like the storage layer 23 and the reference layer 25, and has a direction of magnetization opposite to that of the reference layer 25. The shift canceling layer 27 thus cancels a shift of magnetization reversal characteristic (hysteresis curve) of the storage layer 23 due to a stray magnetic field from the reference layer 25. For example, it is preferable that the shift canceling layer 27 includes CoPt, CoNi, or CoPd. For example, the shift canceling layer 27 comprises a [Co/Pt]n structure obtained by laminating n Co layers and n Pt layers.

The nonmagnetic conductive layer 26 functions as a buffer layer that separates the reference layer 25 and the shift canceling layer 27. The nonmagnetic conductive layer 26 comprises, for example, a metal layer of Pt, W, Ta, Ru or the like.

In the layout of such a memory cell array, the magnetization reversal characteristic of the storage layer 23 of each magnetoresistive element MTJ is adjusted by the shift canceling layer 27 as described above.

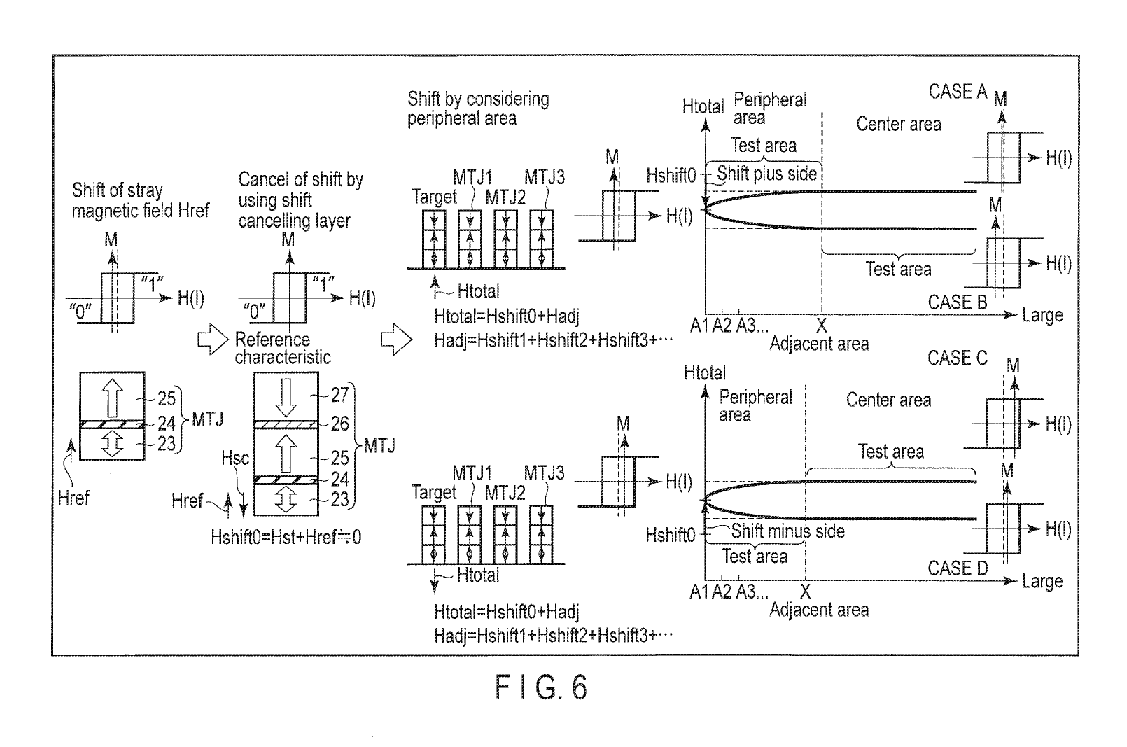

For example, as shown in “Shift of stray magnetic field Href” in FIG. 6, a stray magnetic field Href from the reference layer 25 is applied to the storage layer 23 and shifts the magnetization reversal characteristic of the storage layer 23 to a 1-side.

In order to simplify the following description, the parallel state of the storage layer 23 and the reference layer 25 is called a 0-state (low-resistance state) and the antiparallel state of the storage layer 23 and the reference layer 25 is called a 1-state (high-resistance state). In addition, the horizontal axis of the magnetization reversal characteristic of the storage layer 23 represents a strength (magnetic field strength) H of a magnetic field applied to the storage layer 23 or value I of a spin injection current, and the vertical axis represents magnetization M of the storage layer 23, as an example.

That is, in the example of FIG. 6, stray magnetic field Href from the reference layer 25 shifts the magnetization reversal characteristic of the storage layer 23 to the 1-side in which the storage layer 23 and the reference layer 25 are hardly in the antiparallel state and tend to be in the parallel state.

Therefore, for example, as shown in “Cancel of shift by using shift canceling layer” in FIG. 6, the sum of stray magnetic field Href from the reference layer 25 and a stray magnetic field Hsc from the shift canceling layer 27 is set to zero or a value nearly equal to zero by applying stray magnetic field Hsc from the shift canceling layer 27 to the storage layer 23.

In this manner, the magnetization reversal characteristic of the storage layer 23 of each magnetoresistive element MTJ is adjusted to be symmetric, i.e., the positive direction and the negative direction are substantially equal, with respect to a point at which the strength of the magnetic field applied to the storage layer 23 or the value of the spin injection current is zero.

However, although the magnetization reversal characteristic of a magnetoresistive element MTJ is adjusted by a shift canceling layer 27 in the magnetoresistive element MTJ, the magnetization reversal characteristic is further affected by stray magnetic fields from the other magnetoresistive elements MTJ.

For example, as shown in FIG. 5A, stray magnetic fields Href and Hsc from a reference layer 25 and a shift canceling layer 27 of a magnetoresistive element MTJ0 (target) are applied to a storage layer 23 of magnetoresistive element MTJ0, and at the same time stray magnetic fields Hshift1, Hshift2 and Hshift3 from the other magnetoresistive elements MTJ1, MTJ2 and MTJ3 are further applied to the storage layer 23 of magnetoresistive element MTJ0.

Therefore, the magnetization reversal characteristic of magnetoresistive element MTJ0 is changed by the stray magnetic fields from the other magnetoresistive elements MTJ1, MTJ2 and MTJ3.

For example, as shown in FIG. 3, FIG. 4 and FIG. 5A, a magnetoresistive element MTJ0 is set as a target and the other magnetoresistive elements MTJ1, MTJ2 and MTJ3 located around the target magnetoresistive element MTJ0 are called adjacent cells. In addition, ranges A1, A2, A3, A4, A5, of the adjacent cells considered when testing the magnetization reversal characteristic of magnetoresistive element MTJ0 are called adjacent areas.

The embodiments are based on the premise that stray magnetic fields from the adjacent areas A1, A2, A3, A4, A5, . . . are considered when the magnetization reversal characteristic of the storage layer 23 of each magnetoresistive element is considered.

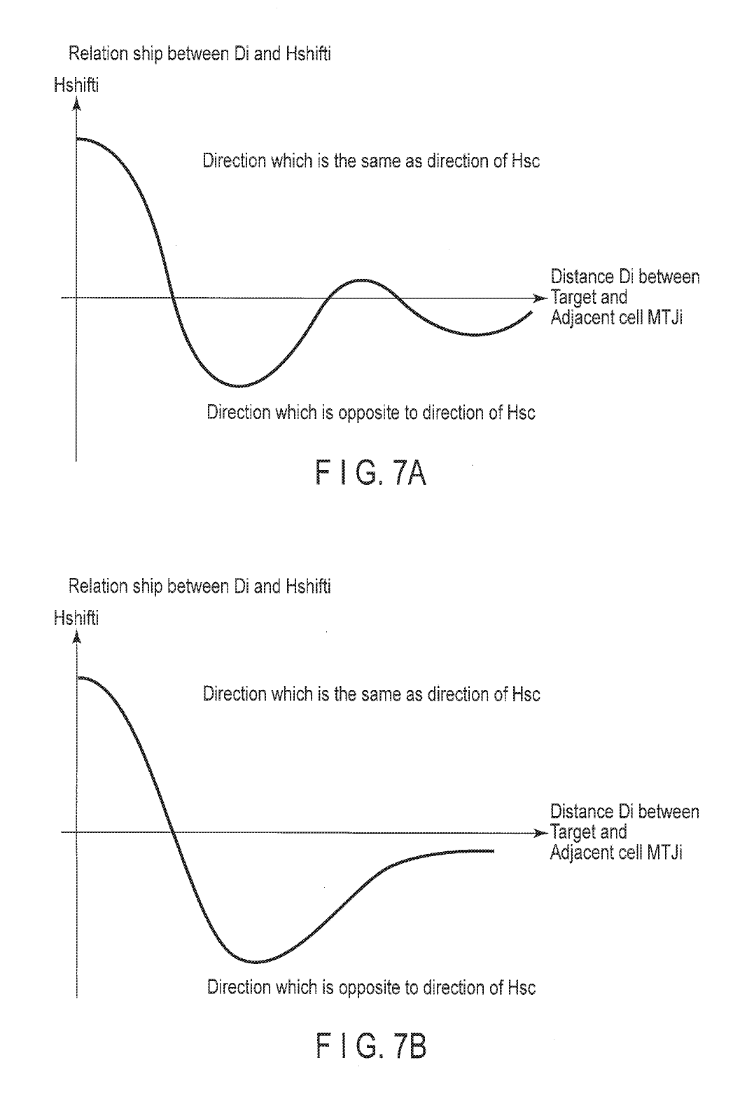

The magnetoresistive elements have characteristic with respect to a stray magnetic field depending on their stacked structure, thickness of each layer and the like, as shown in, for example, FIG. 7A or FIG. 7B.

According to FIG. 7A or FIG. 7B, the size and the direction of stray magnetic fields Hshift1, Hshift2 and Hshift3 applied from the adjacent areas to the storage layer 23 of the target magnetoresistive element MTJ0 are varied according to a distance Di between the target magnetoresistive element MTJ0 and magnetoresistive element MTJi (i=1, 2 or 3) as an adjacent cell.

That is, the size and direction of stray magnetic fields Hshift1, Hshift2 and Hshift3 may be identical to or opposite to stray magnetic field Hsc from the shift canceling layer 27 depending on the distance Di between magnetoresistive element MTJ0 and magnetoresistive element MTJi (i=1, 2 or 3).

In each case, however, the magnetization reversal characteristic of the storage layer 23 of each magnetoresistive element is less affected by the stray magnetic fields from adjacent areas A1, A2, A3, A4, A5, . . . as adjacent areas A1, A2, A3, A4, A5, . . . become large. This means that there is a threshold value x of the adjacent areas at which the influence of the stray magnetic fields from the adjacent areas is stabilized.

In other words, considering the stray magnetic fields from the adjacent areas, magnetization reversal characteristic of each magnetoresistive element in the center area of the memory cell array in which the range of the adjacent areas is equal to the threshold value x has a stable value. In contrast, the magnetization reversal characteristic of each magnetoresistive element in the peripheral area of the memory cell array in which the range of the adjacent areas is less than the threshold value x gradually departs from the stable value toward the edge of the memory cell array.

Considering such variations of the magnetization reversal characteristic of the magnetoresistive elements depending on position in the memory cell array, it turns out that only a magnetoresistive element having a more wrong characteristic (i.e., having a large shift in a hysteresis curve) than a reference characteristic (for example, characteristic of which hysteresis curve is substantially symmetric in the positive and negative directions with respect to a point at which the magnetic field strength or the value of the spin injection current is zero) should be tested in order to test the magnetic memory.

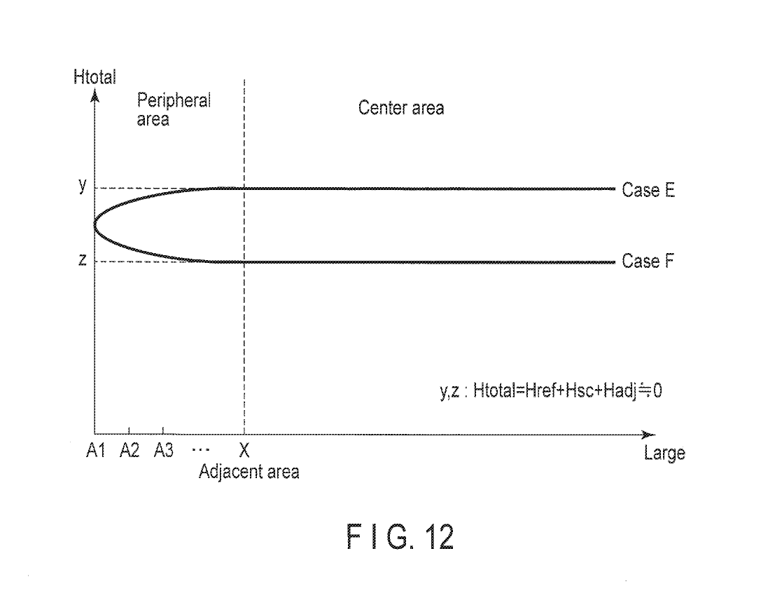

A magnetoresistive element having a wrong characteristic varies depending on which of the following is used: a reference characteristic in which the sum of stray magnetic fields Href and Hsc from the reference layer and the shift canceling layer is zero (for example, Hshift=Href+Hsc≈0 in FIG. 6); and a reference characteristic in which the sum of stray magnetic fields Href, Hsc and Hadj is zero (for example, Htotal=Href+Hsc+Hadj×0 in FIG. 12).

That is, a magnetoresistive element having a wrong characteristic may be in the peripheral area or the center area of the memory cell array depending on, for example, the reference characteristic, type of test and the like.

Therefore, by testing magnetoresistive elements in the peripheral area and not testing magnetoresistive elements in the center area in the former case and by testing magnetoresistive elements in the center area and not testing magnetoresistive elements in the peripheral area in the latter case, magnetoresistive elements to be tested are restricted and the test time can be thereby reduced.

As described above, the magnetization reversal characteristic of each magnetoresistive element in the center area of the memory cell array in which the range of the adjacent areas is equal to the threshold value x has a stable value.

This means that the magnetization reversal characteristic of magnetoresistive elements (valid cells) in the memory cell array can be equalized by using magnetoresistive elements in the center area as valid cells capable of storing data and setting magnetoresistive elements in the peripheral area as dummy cells not used to store data.

[Test Method of First Embodiment]

FIG. 6 shows a test method (method of determining a test area) of the first embodiment.

The present embodiment is based on the premise that stray magnetic field Href from the reference layer 25 to the storage layer 23 and stray magnetic field Hsc from the shift canceling layer 27 to the storage layer 23 compensate each other and the sum of them Hshift0 (=Href+Hsc) is substantially zero as shown in “Canceling of shift by using shift canceling layer” of FIG. 6. In this case, as shown in “Shift by considering peripheral area” of FIG. 6, the magnetization reversal characteristic of magnetoresistive element MTJ0 varies in the following four patterns by stray magnetic field Hadj (=Hshift1, Hshift2, Hshift3, . . . ) from magnetoresistive elements MTJ1, MTJ2, MTJ3, . . . in the peripheral area to the storage layer 23 of the target magnetoresistive element MTJ0.

Cases A and B

In cases A and B, the sum Htotal of stray magnetic fields applied to the storage layer 23 of the target magnetoresistive element MTJ0 has a direction of magnetization identical to that of the reference layer 25. That is, the magnetization reversal characteristic of magnetoresistive element MTJ0 is shifted from the reference characteristic to the positive side (right side). The amount of the shift depends on a value of Htotal (=Hshift0+Hadj).

In the center area of the memory cell array in which the range of the adjacent areas is equal to the threshold value x, Hadj (=Hshift1+Hshift2+Hshift3+ . . . ) and Htotal are at a stable value. In contrast, in the peripheral area of the memory cell array in which the range of the adjacent areas is less than the threshold value x, Hadj (=Hshift1+Hshift2+Hshift3+ . . . ) and Htotal vary according to position.

In case A, a magnetization reversal characteristic of a magnetoresistive element in the peripheral area gradually becomes distant from the stable value or the reference characteristic (Hshift0) as the magnetoresistive element is closer to the edge of the memory cell array. In this case, the magnetization reversal characteristic of the magnetoresistive elements located in the peripheral area of the memory cell array is the most distant from the reference characteristic (Hshift0).

Therefore, in case A, the peripheral area is used as a test area and only the magnetoresistive elements in the peripheral area should be tested.

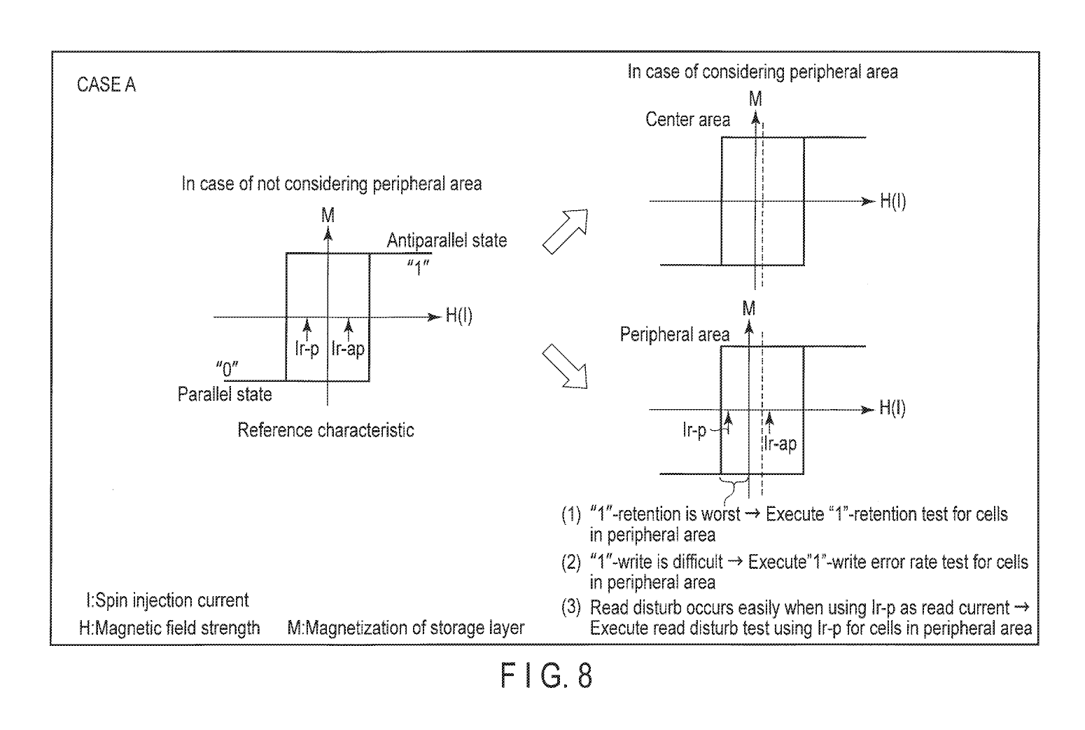

As shown in FIG. 8, for example, the magnetization reversal characteristic of the magnetoresistive elements in the peripheral area is shifted most to the positive side (right side) with respect to the reference characteristic.

In this case, it is easy to transition the magnetoresistive elements to the 0-state (low-resistance state) since the magnetoresistive elements can be transitioned to the 0-state by a small magnetic field H or a small write current I. In addition, it is difficult to transition the magnetoresistive elements to the 1-state (high-resistance state) since a large magnetic field H or a large write current I is necessary for transitioning the magnetoresistive elements to the 1-state.

This means that retention of the magnetoresistive elements in the 1-state worsens and a 1-write becomes difficult. Therefore, in case A, a 1-retention test or a 1-write error test should be executed for the magnetoresistive elements in the peripheral area.

In case A, since the magnetization reversal characteristic of the magnetoresistive elements in the peripheral area is shifted most to the positive side (right side) with respect to the reference characteristic, read disturb, namely, a 0-write (erroneous write) tends to occur in the magnetoresistive elements in the peripheral area when a read current Ir-p on the parallel side (left side) is used as a read current.

Therefore, in case A, a read disturb test should be executed for the maanetoresistive elements in the peripheral area when Ir-p is used as a read current.

When a read current Ir-ap on the antiparallel side (right side) is used as a read current, read disturb tends to occur in the magnetoresistive elements in the center area more than in the magnetoresistive elements in the peripheral area. In this case, a read disturb test should be executed for the magnetoresistive elements in the center area.

In case B, a magnetization reversal characteristic of a magnetoresistive element in the peripheral area gradually becomes distant from the stable value and gradually becomes close to the reference characteristic (Hshift0) as the magnetoresistive element is closer to the edge of the memory cell array. In this case, the magnetoresistive elements located in the center area of the memory cell array are the most distant from the reference characteristic (Hshift0).

Therefore, in case B, the center area is used as a test area and only the magnetoresistive elements in the center area should be tested.

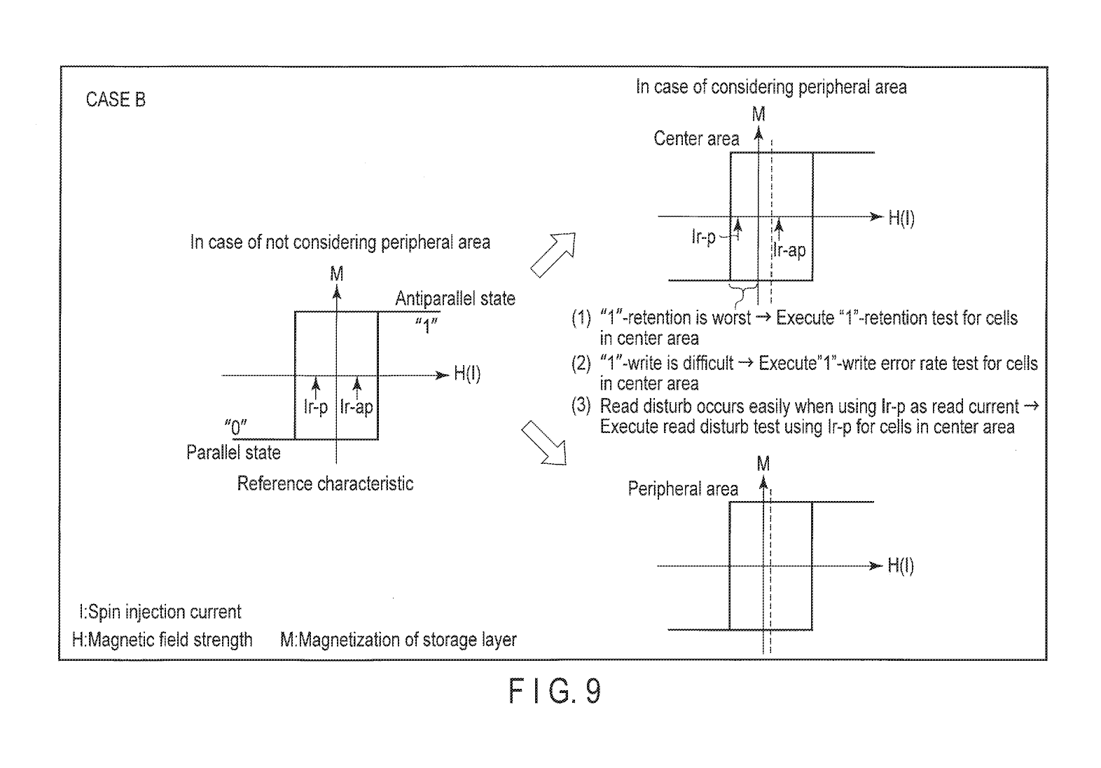

As shown in FIG. 9, for example, the magnetization reversal characteristic of the magnetoresistive elements in the center area is shifted most to the positive side (right side) with respect to the reference characteristic.

This means that retention of the magnetoresistive elements in the 1-state worsens and a 1-write becomes difficult. Therefore, in case B, a 1-retention test or a 1-write error test should be executed for the magnetoresistive elements in the center area.

In case B, since the magnetization reversal characteristic of the magnetoresistive elements in the center area is shifted most to the positive side (right side) with respect to the reference characteristic, read disturb, namely, a 0-write (erroneous write) tends to occur in the magnetoresistive elements in the center area when read current Ir-p on the parallel side (left side) is used as a read current.

Therefore, in case B, a read disturb test should be executed for the magnetoresistive elements in the center area when Ir-p is used as a read current.

When read current Ir-ap on the antiparallel side (right side) is used as a read current, read disturb tends to occur in the magnetoresistive elements in the peripheral area more than in the magnetoresistive elements in the center area. In this case, a read disturb test should be executed for the magnetoresistive elements in the peripheral area.

Cases C and D

In cases C and D, the sum Htotal of stray magnetic fields applied to the storage layer 23 of the target magnetoresistive element MTJ0 has a direction of magnetization opposite to that of the reference layer 25. That is, the magnetization reversal characteristic of magnetoresistive element MTJ0 is shifted from the reference characteristic to the negative side (left side). The amount of the shift depends on a value of Htotal (=Hshift0+Hadj).

In the center area of the memory cell array in which the range of the adjacent areas is equal to the threshold value x, Hadj (=Hshift1+Hshift2+Hshift3+ . . . ) and Htotal are at a stable value. In contrast, in the peripheral area of the memory cell array in which the range of the adjacent areas is less than the threshold value x, Hadj (=Hshift1+Hshift2+Hshift3+ . . . ) and Htotal vary according to position.

In case C, a magnetization reversal characteristic of a magnetoresistive element in the peripheral area gradually becomes distant from the stable value and gradually becomes close to the reference characteristic (Hshift0) as the magnetoresistive element is closer to the edge of the memory cell array. In this case, the magnetization reversal characteristic of the magnetoresistive elements located in the center area of the memory cell array is the most distant from the reference characteristic (Hshift0).

Therefore, in case C, the center area is used as a test area and only the magnetoresistive elements in the center area should be tested.

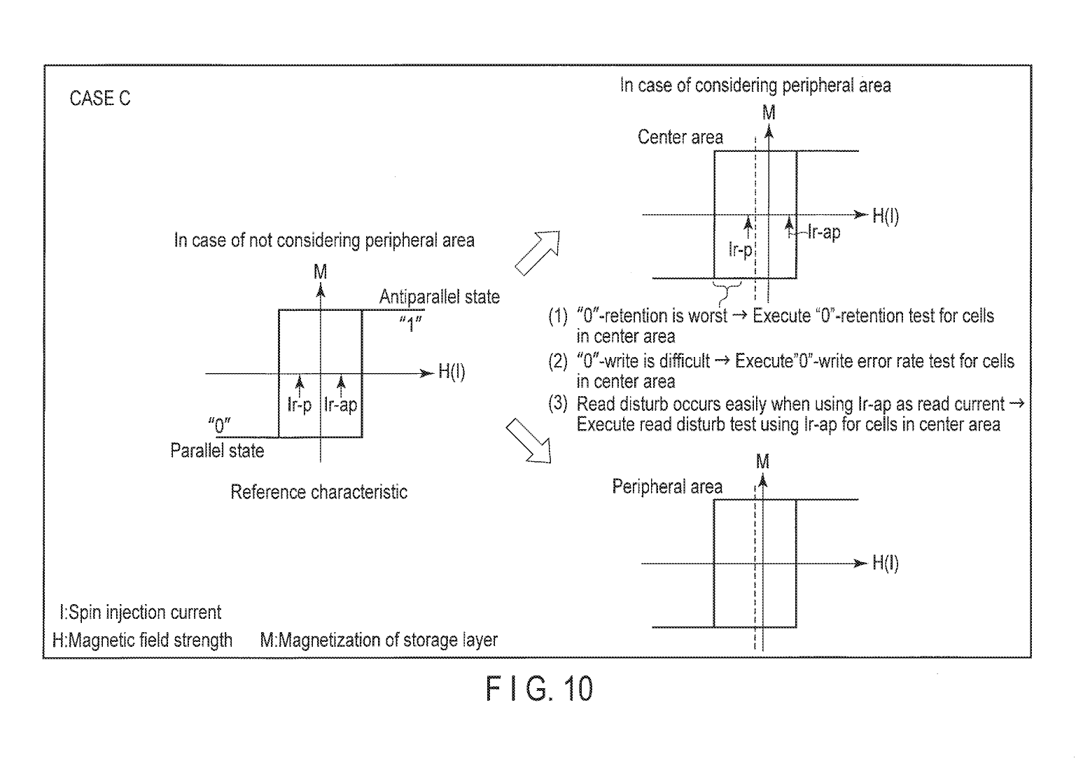

As shown in FIG. 10, for example, the magnetization reversal characteristic of the magnetoresistive elements in the center area is shifted most to the negative side (left side) with respect to the reference characteristic.

In this case, it is easy to transition the magnetoresistive elements to the 1-state (high-resistance state) since the magnetoresistive elements can be transitioned to the 1-state by a small magnetic field H or a small write current I. In addition, it is difficult to transition the magnetoresistive elements to the 0-state (low-resistance state) since a large magnetic field H or a large write current I is necessary for transitioning the magnetoresistive elements to the 0-state.

This means that retention of the magnetoresistive elements in the 0-state worsens and a 0-write becomes difficult. Therefore, in case C, a 0-retention test or a 0-write error test should be executed for the magnetoresistive elements in the center area.

In case C, since the magnetization reversal characteristic of the magnetoresistive elements in the center area is shifted most to the negative side (left side) with respect to the reference characteristic, read disturb, namely, a 1-write (erroneous write) tends to occur in the magnetoresistive elements in the center area when read current Ir-ap on the antiparallel side (right side) is used as a read current.

Therefore, in case C, a read disturb test should be executed for the magnetoresistive elements in the center area when Ir-ap is used as a read current.

When read current Ir-p on the parallel side (left side) is used as a read current, read disturb tends to occur in the magnetoresistive elements in the peripheral area more than in the magnetoresistive elements in the center area. In this case, a read disturb test should be executed for the magnetoresistive elements in the peripheral area.

In case D, a magnetization reversal characteristic of a magnetoresistive element in the peripheral area gradually becomes distant from the stable value or the reference characteristic (Hshift0) as the magnetoresistive element is closer to the edge of the memory cell array. In this case, the magnetoresistive elements located in the peripheral area of the memory cell array are the most distant from the reference characteristic (Hshift0).

Therefore, in case D, the peripheral area is used as a test area and only the magnetoresistive elements in the peripheral area should be tested.

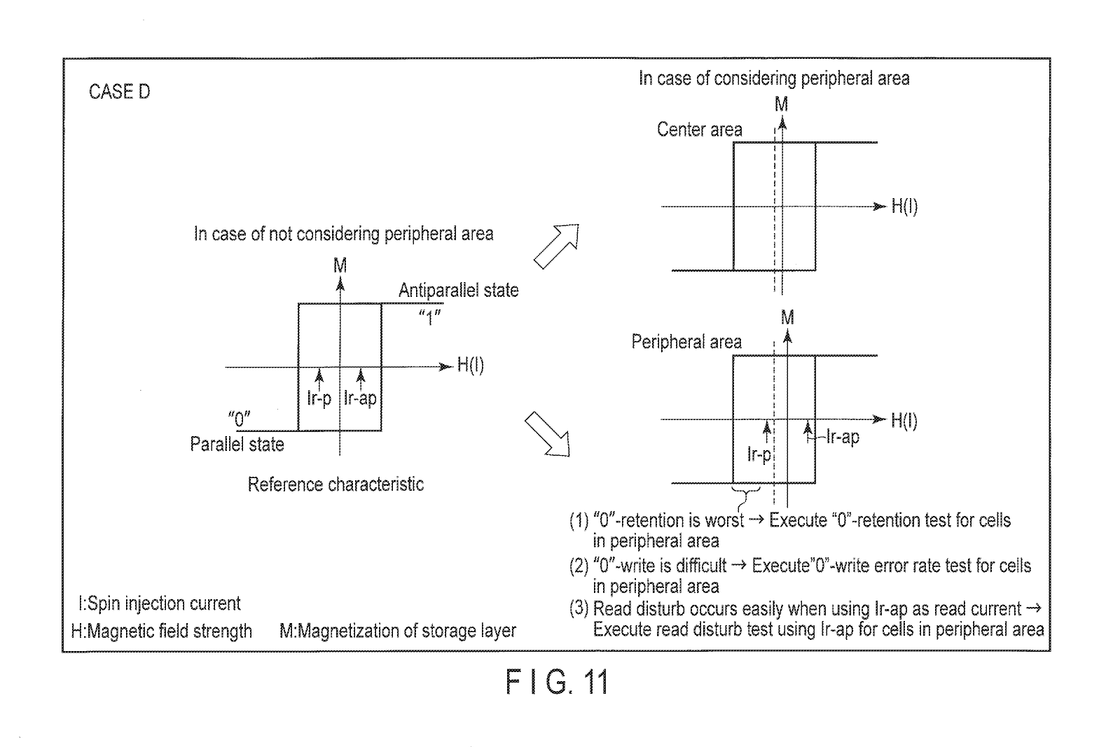

As shown in FIG. 11, for example, the magnetization reversal characteristic of the magnetoresistive elements in the peripheral area is shifted most to the negative side (left side) with respect to the reference characteristic.

This means that retention of the magnetoresistive elements in the 0-state worsens and a 0-write becomes difficult. Therefore, in case D, a 0-retention test or a 0-write error test should be executed for the magnetoresistive elements in the peripheral area.

In case D, since the magnetization reversal characteristic of the magnetoresistive elements in the peripheral area is shifted most to the negative side (left side) with respect to the reference characteristic, read disturb, namely, a 1-write (erroneous write) tends to occur in the magnetoresistive elements in the peripheral area when read current Ir-ap on the antiparallel side (right side) is used as a read current.

Therefore, in case D, a read disturb test should be executed for the magnetcresistive elements in the peripheral area when Ir-ap is used as a read current.

When read current Ir-p on the parallel side (left side) is used as a read current, read disturb tends to occur in the magnetoresistive elements in the center area more than in the magnetoresistive elements in the peripheral area. In this case, a read disturb test should be executed for the magnetoresistive elements in the center area.

[Test Method of Second Embodiment]

FIG. 12 shows a test method (method of determining a test area) of the second embodiment.

The present embodiment is based on the premise that stray magnetic field Href from the reference layer to the storage layer, stray magnetic field Hsc from the shift canceling layer to the storage layer and stray magnetic field Hadj from adjacent areas to the storage layer compensate each other and the sum of them Htotal (=Href+Hsc+Hadj) is substantially zero. That is, Href, Hsc and Hadj are adjusted such that y or z is substantially zero in FIG. 12.

In this case, the magnetization reversal characteristic of magnetoresistive elements varies in the following two patterns.

Cases E and F

When the magnetization reversal characteristic of the magnetoresistive elements in the center area of the memory cell array in which the range of the adjacent areas is at the threshold value x is set as a reference characteristic, Htotal varies depending on position in the peripheral area of the memory cell array in which the range of the adjacent areas is less than the threshold value x.

That is, a magnetization reversal characteristic of a magnetoresistive element in the peripheral area gradually becomes distant from the reference characteristic (Htotal=0) in the positive (right) or negative (left) direction as the magnetoresistive element is closer to the edge of the memory cell array. In this case, the magnetization reversal characteristic of the magnetoresistive elements located in the peripheral area of the memory cell array is the most distant from the reference characteristic (Htotal=0).

Therefore, in cases E and F, the peripheral area is used as a test area and only the magnetoresistive elements in the peripheral area should be tested.

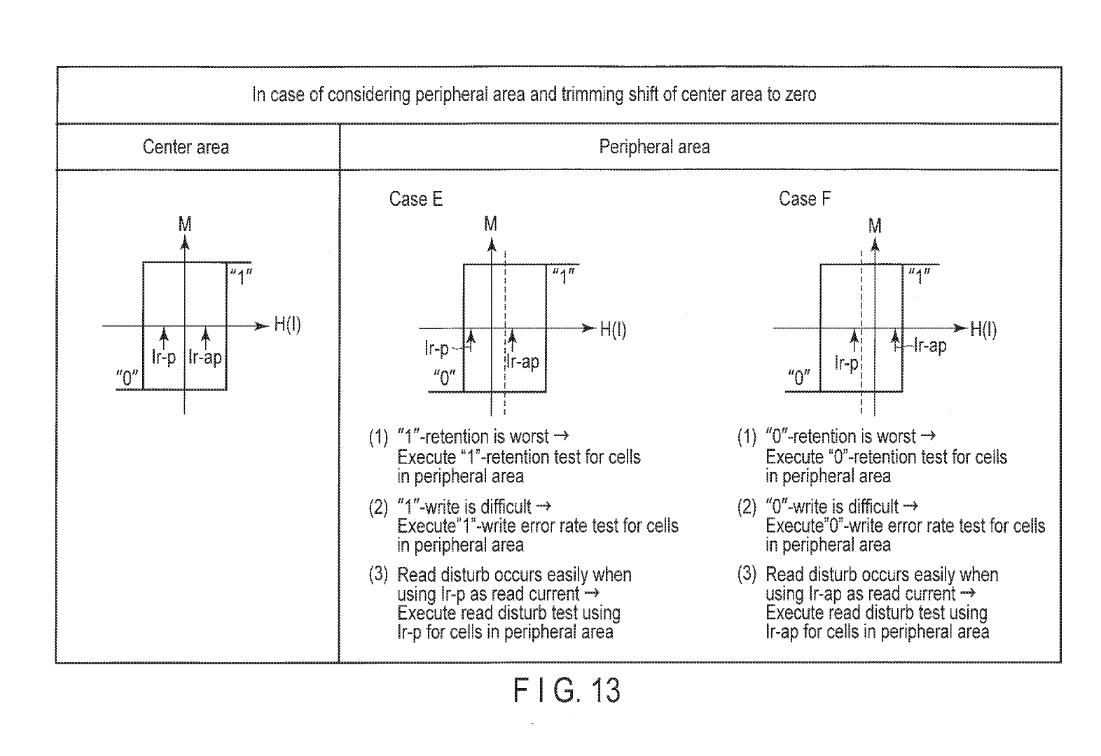

As shown in FIG. 13, for example, the magnetization reversal characteristic of the magnetoresistive elements in the peripheral area is shifted most to the positive side (right side) with respect to the reference characteristic in case E.

In this case, it is easy to transition the magnetoresistive elements to the 0-state (low-resistance state) since the magnetoresistive elements can be transitioned to the 0-state by a small magnetic field H or a small write current I. In addition, it is difficult to transition the magnetoresistive elements to the 1-state (high-resistance state) since a large magnetic field H or a large write current I is necessary for transitioning the magnetoresistive elements to the 1-state.

This means that retention of the magnetoresistive elements in the 1-state worsens and a 1-write becomes difficult. Therefore, in case E, a 1-retention test or a 1-write error test should be executed for the magnetoresistive elements in the peripheral area.

In case E, since the magnetization reversal characteristic of the magnetoresistive elements in the peripheral area is shifted most to the positive side (right side) with respect to the reference characteristic, read disturb tends to occur in the magnetoresistive elements in the peripheral area when read current Ir-p on the parallel side (left side) is used as a read current.

Therefore, in case E, a read disturb test should be executed for the magnetoresistive elements in the peripheral area when Ir-p is used as a read current.

When read current Ir-ap on the antiparallel side (right side) is used as a read current, read disturb tends to occur in the magnetoresistive elements in the center area more than in the magnetoresistive elements in the peripheral area. In this case, a read disturb test should be executed for the magnetoresistive elements in the center area.

As shown in FIG. 13, in case F, the magnetization reversal characteristic of the magnetoresistive elements in the peripheral area is shifted most to the negative side (left side) with respect to the reference characteristic.

In this case, it is easy to transition the magnetoresistive elements to the 1-state (low-resistance state) since the magnetoresistive elements can be transitioned to the 1-state by a small magnetic field H or a small write current I. In addition, it is difficult to transition the magnetoresistive elements to the 0-state (low-resistance state) since a large magnetic field H or a large write current I is necessary for transitioning the magnetoresistive elements to the 0-state.

This means that retention of the magnetoresistive elements in the 0-state worsens and a 0-write becomes difficult. Therefore, in case F, a 0-retention test or a 0-write error test should be executed for the magnetoresistive elements in the peripheral area.

In case E, since the magnetization reversal characteristic of the magnetoresistive elements in the peripheral area is shifted most to the negative side (left side) with respect to the reference characteristic, read disturb tends to occur in the magnetoresistive elements in the peripheral area when read current Ir-ap on the antiparallel side (right side) is used as a read current.

Therefore, in case F, a read disturb test should be executed for the magnetoresistive elements in the peripheral area when Ir-ap is used as a read current.

When read current Ir-p on the parallel side (left side) is used as a read current, read disturb tends to occur in the magnetoresistive elements in the center area more than in the magnetoresistive elements in the peripheral area. In this case, a read disturb test should be executed for the magnetoresistive elements in the center area.

[Test Method of Third Embodiment]

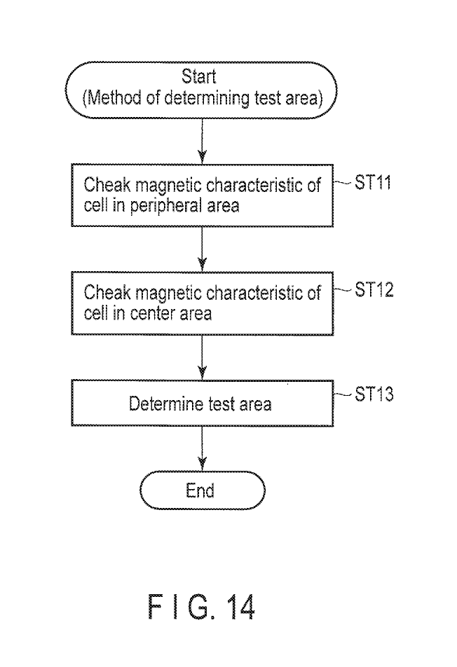

FIG. 14 shows a test method (method of determining a test area) of the third embodiment.

The test method relates to a method of determining a test area depending on type of a developed magnetic memory.

First, a predetermined type of a magnetic memory is manufactured as a sample by using a manufacturing line.

Next, for example, magnetic characteristics of memory cells in a center area and a peripheral area of the sample is checked (steps ST11 to ST12).

As described above, a magnetic characteristic of each memory cell is constant in the center area and variable in the peripheral area.

Therefore, which of the peripheral area and the center area includes memory cells having a characteristic the most distant from a reference characteristic is confirmed. That is, which of the above cases A to E is applicable is confirmed.

Then, the peripheral area is used as a test area if memory cells having a characteristic the most distant from the reference characteristic are present in the peripheral area (cases A, D, E and F), and the center area is used as a test area if memory cells having a characteristic the most distant from the reference characteristic are present in the center area (cases B and C) (step ST13).

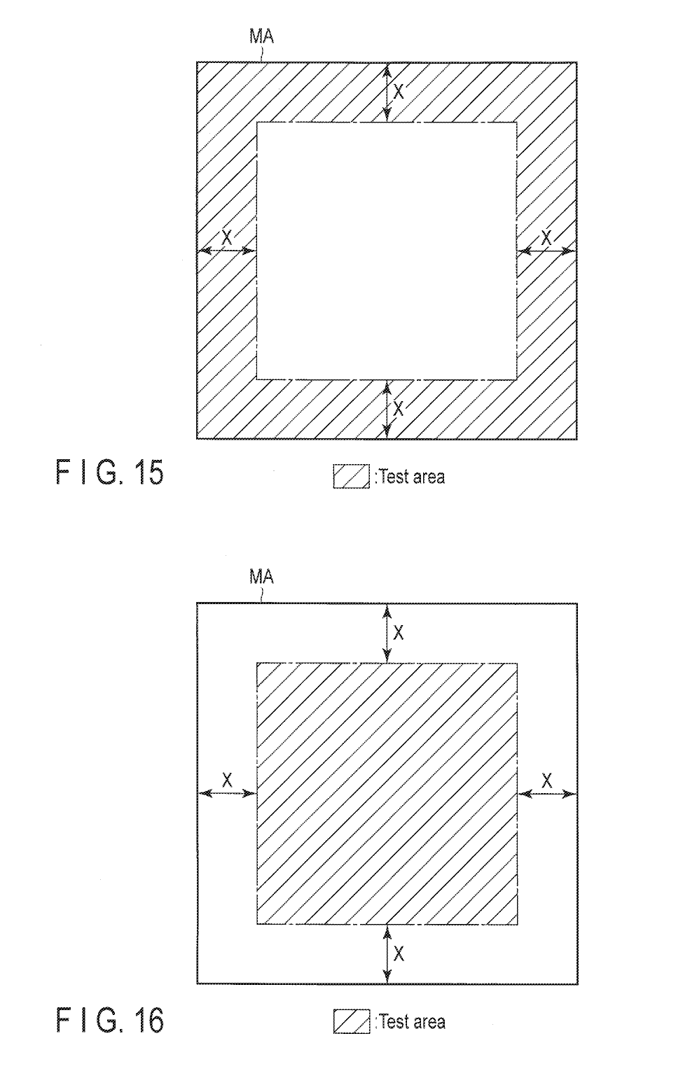

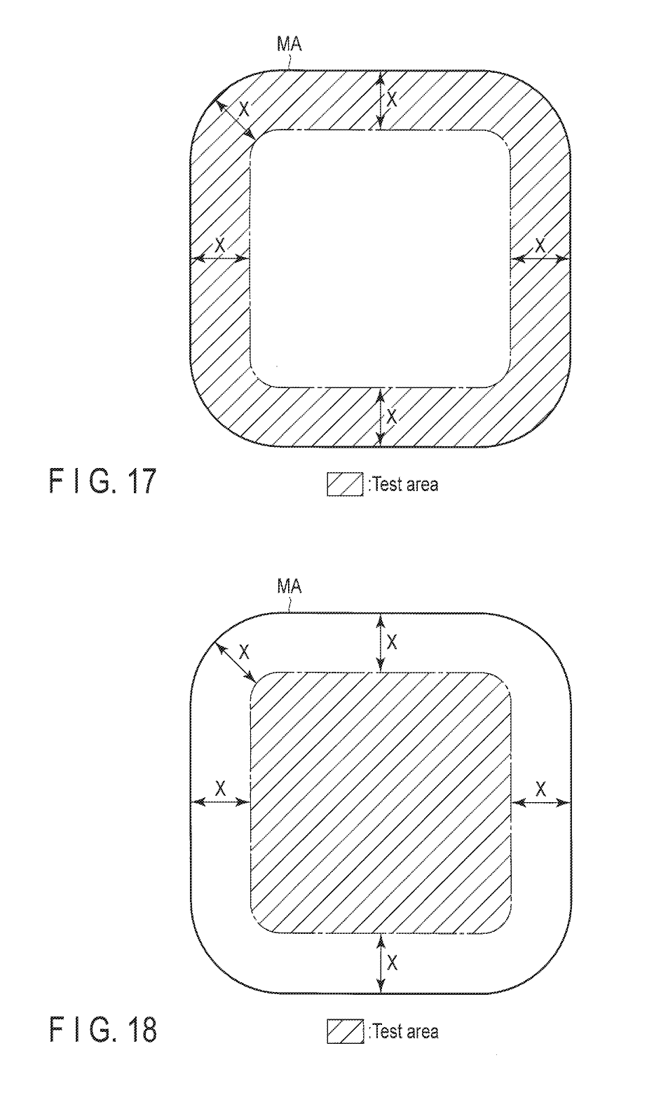

FIG. 15, FIG. 16, FIG. 17 and FIG. 18 show examples of the test area.

FIG. 15 and FIG. 16 show examples in which a memory cell array MA is quadrangular.

In this case, if the peripheral area is used as a test area, the test area is an area of a threshold value (corresponding to the number of magnetoresistive elements) x from the edge of the memory cell array MA.

If the center area is used as a test area, the test area is an area excluding the area of the threshold value x from the edge of the memory cell array MA.

FIG. 17 and FIG. 18 show examples in which the corners of the memory cell array MA of FIG. 15 and FIG. 16 are rounded.

In this case, too, if the peripheral area is used as a test area, the test area is an area of the threshold value x from the edge of the memory cell array MA. If the center area is used as a test area, the test area is an area excluding the area of the threshold value x from the edge of the memory cell array MA.

After the test area is determined, magnetic memories of the predetermined type are manufactured (mass-produced) by using the manufacturing line. In the manufacturing process of the magnetic memories, the test time can be reduced by testing the magnetic memories in the test area determined by the sample.

As described above, a test area is determined per product. That is, the same test area is used for to the same products (products manufactured in the same manufacturing line).

The memory cell array MA may have a shape other than a quadrangle (including a rounded-corner quadrangle). For example, the memory cell array MA may be circular or elliptical.

[Method of Manufacturing Magnetic Memory of Fourth Embodiment]

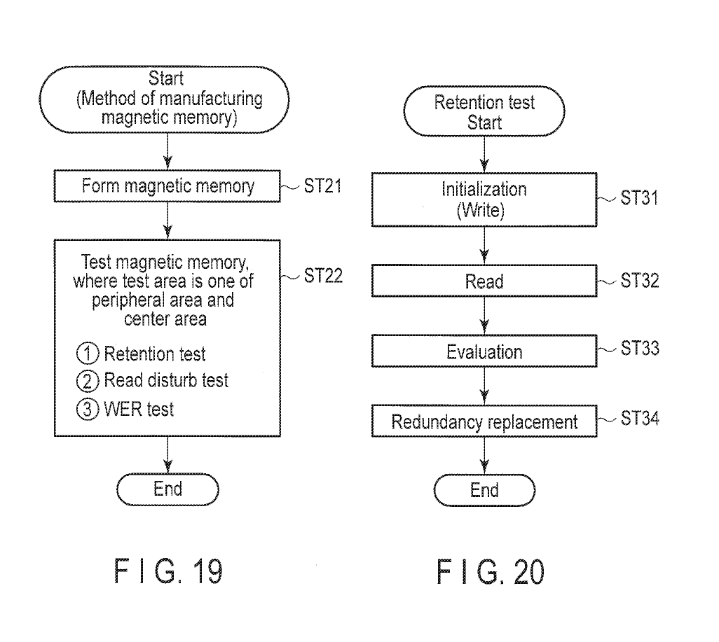

FIG. 19 shows a method of manufacturing a magnetic memory of the fourth embodiment.

First, a magnetic memory is formed (step ST21).

After that, the magnetic memory is tested (step ST22).

That is, a fail bit that does not satisfy the specifications of the magnetic memory is detected by the test and replaced with a pass bit that satisfies the specifications, using, for example, a redundancy technique.

By feeding back the result of the test, it is also possible to execute calibration of the magnetic memory and reduce the tendency of fail bits to occur in the following manufacturing process of the magnetic memory.

A retention test, a read disturb test, a write error rate (WER) test and the like are necessary for determining whether the specification of the magnetic memory is satisfied.

Retention is an index indicative of a time for which the magnetic memory can continuously store data. Read disturb is indicative of a phenomenon in which the magnetization inversion of the storage layer is caused by a read current. A write error is indicative of a phenomenon in which the probability of writing data accurately is less than 1 because of thermal fluctuation.

When executing these tests, the magnetic memory should preferably be in a test magnetic field and/or the temperature of the magnetic memory should preferably be increased or decreased, in order to accelerate the tests.

The strength of the test magnetic field is determined in consideration of an external magnetic field that the magnetic memory may be subjected to, in order to guarantee that a device to which the magnetic memory is applied always functions normally. For example, it is known that a mobile device is subjected to an external magnetic field of 100 Oe. Therefore, the test should preferably be executed by using a test magnetic field of, for example, 100 Oe or more.

The temperature of the magnetic memory is also determined in consideration of an external temperature that the magnetic memory may be subjected to, in order to guarantee that a device to which the magnetic memory is applied always functions normally.

For example, if a defect tends to occur at high temperature (i.e., if the worst is at high temperature), the magnetic memory should preferably be tested while keeping the magnetic memory at a temperature of 80° C. or higher (85° C., 150° C., etc.). If a defect tends to occur at low temperature (i.e., if the worst is at low temperature), the magnetic memory should preferably be tested while keeping the magnetic memory at a temperature of 0° C. or lower (−60° C., −120° C., etc.).

(1) Retention Test

For example, a retention test can be accelerated by executing the retention test while generating a test magnetic field by the test magnetic field generating portion 14 or increasing the temperature of the magnetic memory by the temperature control portion 15 (if the worst is at high temperature) in the test system of FIG. 1. In this case, the retention test can be executed in a short time of about 10 s.

The controller 11 executes the retention test by executing at least the following subsequent steps.

First Step

First data is written to the magnetic memory.

Second Step

Second data is read from the magnetic memory.

Third Step

The characteristics of the magnetic memory are evaluated by comparing the first and second data.

More specifically, the retention test is executed in accordance with the flowchart of FIG. 20.

First, data is written to the magnetic memory (step ST31).

For instance, initialization for causing all the magnetoresistive elements of the magnetic memory to have the same data is executed. That is, all the magnetoresistive elements of the magnetic memory are set to a low-resistance state (0-state) or a high-resistance state (1-state) by the write.

After that, the magnetic memory is left for a certain period. At this time, the magnetic memory should preferably be left in a test magnetic field having a direction of magnetization opposite to that of the storage layer of the magnetoresistive elements (for example, 100 Oe) or at increased temperature (for example, 85 or 150° C.).

Next, data is read from the magnetic memory (step ST32).

Then, the characteristics of the magnetic memory are evaluated by comparing the write and read data (step ST33).

For instance, in the evaluation, fail bits in which the write data is not identical to the read data are detected, and whether the number of fail bits is less than a predetermined value is determined.

Lastly, if the number of the fail bits is less than the predetermined value, the magnetic memory is determined to satisfy the specifications and redundancy replacement for replacing the fail bits with pass bits is executed (step ST34).

Conversely, if the number of fail bits is greater than or equal to the predetermined value, the magnetic memory is determined not to satisfy the specifications, and is therefore determined to be defective.

(2) Read Disturb Test

For example, a read disturb test can be accelerated by executing the read disturb test while generating a test magnetic field by the test magnetic field generating portion 14 or increasing the temperature of the magnetic memory by the temperature control portion 15 (if the worst is at high temperature) in the test system of FIG. 1. In this case, the read disturb test can be executed in a short time of about 12 s.

The controller 11 executes the read disturb test by executing at least the following subsequent steps.

First Step

First data is written to the magnetic memory.

Second Step

Second data is read from the magnetic memory.

Third Step

The characteristics of the magnetic memory are evaluated by comparing the first and second data.

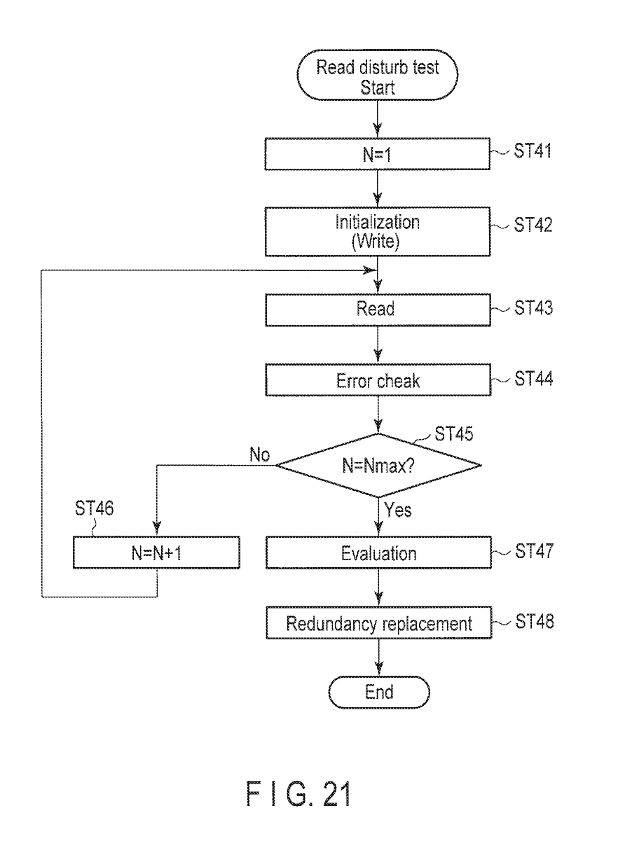

More specifically, the read disturb test is executed in accordance with the flowchart of FIG. 21.

First, data is written to the magnetic memory (steps ST41 to ST42).

For instance, initialization for causing all the magnetoresistive elements of the magnetic memory to have the same data is executed. That is, all the magnetoresistive elements of the magnetic memory are set to a low-resistance state (0-state) or a high-resistance state (1-state) by the write.

Next, data is read from the magnetic memory (step ST43).

The data should preferably be read while applying a test magnetic field having a direction of magnetization opposite to that of the storage layer of the magnetoresistive elements (for example, 100 Oe) or increasing the temperature of the magnetic memory (for example, 85 or 150° C.).

Next, fail bits in which the write data is not identical to the read data are detected by comparing the write and read data (error check). The error check is executed Nmax times for each magnetoresistive element of the magnetic memory. Nmax is a natural number not less than 2 (steps ST44 to ST46).

In the read disturb test, however, the error check (step ST44) may be executed a predetermined number of times Ncheck included in the Nmax times (Ncheck<Nmax). For instance, if Nmax is 100000, i.e., if data reading (step ST43) is iterated 100000 times, the number Ncheck of times of the error check (step ST44) may be 5.

In this case, the error check is executed, for example, when the loop count of reading reaches 10, 100, 1000, 10000 and 100000 (5 times in total).

By thus reducing the number Ncheck of times of the error check, the test time can be reduced.

Next, the magnetic memory is evaluated based on the number of times each magnetoresistive element of the magnetic memory becomes a fail bit (step ST47).

For instance, in the evaluation, it is determined whether the number of times each magnetoresistive element becomes a fail bit is lower than a predetermined value.

Lastly, if the number of times a magnetoresistive element becomes a fail bit is lower than the predetermined value, the magnetoresistive element is determined as a pass bit. In contrast, if the number of times a magnetoresistive element becomes a fail bit is greater than or equal to the predetermined value, the magnetoresistive element is determined as a fail bit and redundancy replacement for replacing the fail bit with a pass bit is executed (step ST48).

(3) Write Error Rate (WER) Test

For example, a WER test can be accelerated by executing the WER test while generating a test magnetic field by the test magnetic field generating portion 14 or decreasing the temperature of the magnetic memory by the temperature control portion 15 (if the worst is at low temperature) in the test system of FIG. 11. In this case, the WER test can be executed in a short time of about 24 s.

The controller 11 executes the WER test by executing at least the following subsequent steps.

First Step

First data is written to the magnetic memory.

The data should preferably be written while applying a test magnetic field (for example, 100 Oe) to the magnetic memory or decreasing the temperature of the magnetic memory (for example, −60 or −120° C.).

Second Step

Second data is read from the magnetic memory.

Third Step

The characteristics of the magnetic memory are evaluated by comparing the first and second data.

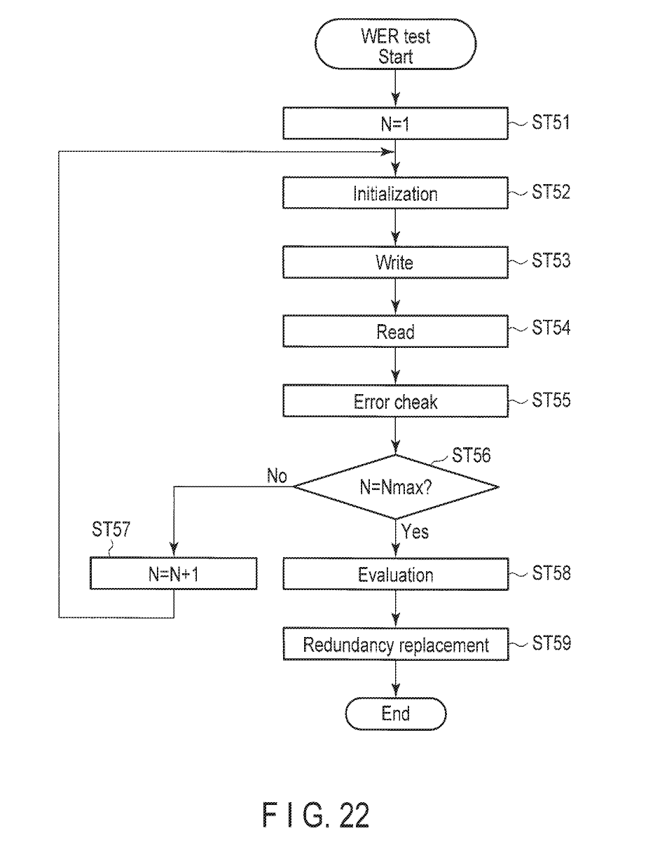

More specifically, the WER test is executed in accordance with the flowchart of FIG. 22.

First, data is written to the magnetic memory (steps ST51 to ST52).

For instance, initialization for causing all the magnetoresistive elements of the magnetic memory to have the same data is executed. That is, all the magnetoresistive elements of the magnetic memory are set to a low-resistance state (0-state) or a high-resistance state (1-state) by the write.

Next, data is written to the magnetic memory 13 again (step ST53).

The write is executed to reverse data in all the magnetoresistive elements of the magnetic memory. The write should preferably be executed while a test magnetic field having a direction of magnetization identical to that of the storage layer before the write, i.e., having a direction of magnetization opposite to that of the storage layer expected after the write, is being applied to all the magnetoresistive elements of the magnetic memory.

In addition, the write should preferably be executed while increasing the temperature of the magnetic memory.

Next, data is read from the magnetic memory (step ST54).

Then, fail bits in which the write data is not identical to the read data are detected by comparing the write and read data (error check). The error check is executed Nmax times for each magnetoresistive element of the magnetic memory. Nmax is a natural number not less than 2 (steps ST55 to ST57).

After that, the magnetic memory is evaluated based on the number of times each magnetoresistive element of the memory becomes a fail bit (step ST58).

For instance, in the evaluation, it is determined whether the number of times each magnetoresistive element becomes a fail bit is lower than a predetermined value.

Lastly, if the number of times a magnetoresistive element becomes a fail bit is lower than the predetermined value, the magnetoresistive element is determined as a pass bit. In contrast, if the number of times a magnetoresistive element becomes a fail bit is greater than or equal to the predetermined value, the magnetoresistive element is determined as a fail bit and redundancy replacement for replacing the fail bit with a pass bit is executed (step ST59).

[Magnetic Memory of Fifth Embodiment]

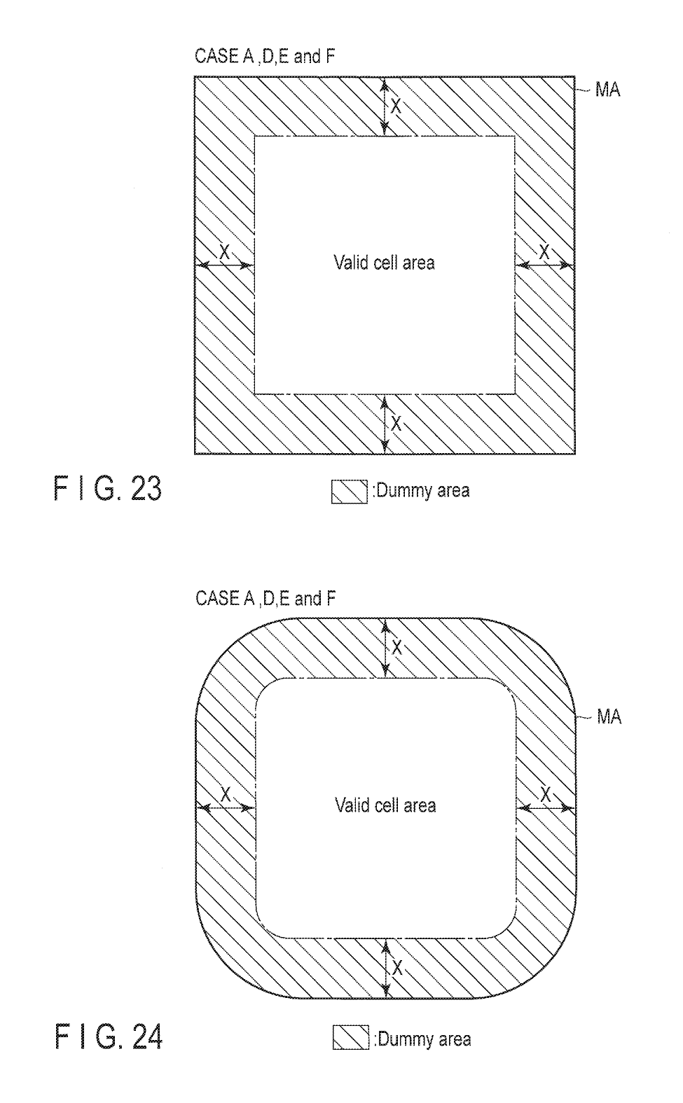

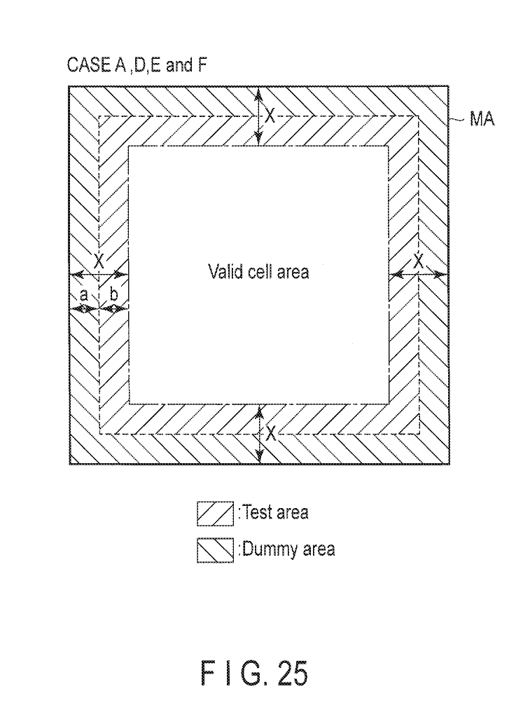

FIG. 23, FIG. 24 and FIG. 25 show a memory cell array of a magnetoresistive element of the fifth embodiment.

The first to fourth embodiments are related to a technique for restricting a test area. In contrast, the fifth embodiment is related to a technique for setting all or a part of magnetoresistive elements in a peripheral area as dummy cells not used for storing data, when magnetoresistive elements having a characteristic the most distant from a reference characteristic are located in the peripheral area.

For example, in cases A and D of the first embodiment and cases E and F of the second embodiment, all or a part of the peripheral area is set as dummy cells. The characteristic of the magnetoresistive elements in the memory cell array (center area) MA is thereby equalized.

FIG. 23 and FIG. 24 show examples in which magnetoresistive elements in the area (peripheral area) of the threshold value x from the edge of the memory cell array MA are set as dummy cells.

FIG. 25 shows an example in which magnetoresistive elements in an area of a (corresponding to the number of magnetoresistive elements) from the edge of the memory cell array MA are set as dummy cells (a<x).

In this case, a characteristic of magnetoresistive elements in a range of b (=x−a) is different from the characteristic of the magnetoresistive elements in the center area, but the difference is small. Therefore, the magnetoresistive elements in the range of b are set as valid cells capable of storing data and the range of b should preferably be a test area.

The threshold value x is, for example, up to the Xth adjacent cells which are the Xth closest to the edge of the memory cell array MA. X is, for example, 8.

If X is 8, a may be 3. That is, memory cells from the first adjacent cells which are the closest to the edge of the memory cell array MA to the third adjacent cells which are the third closest to the edge of the memory cell array MA can be set as dummy cells.

### Application Example

A magnetic memory as an application example is described.

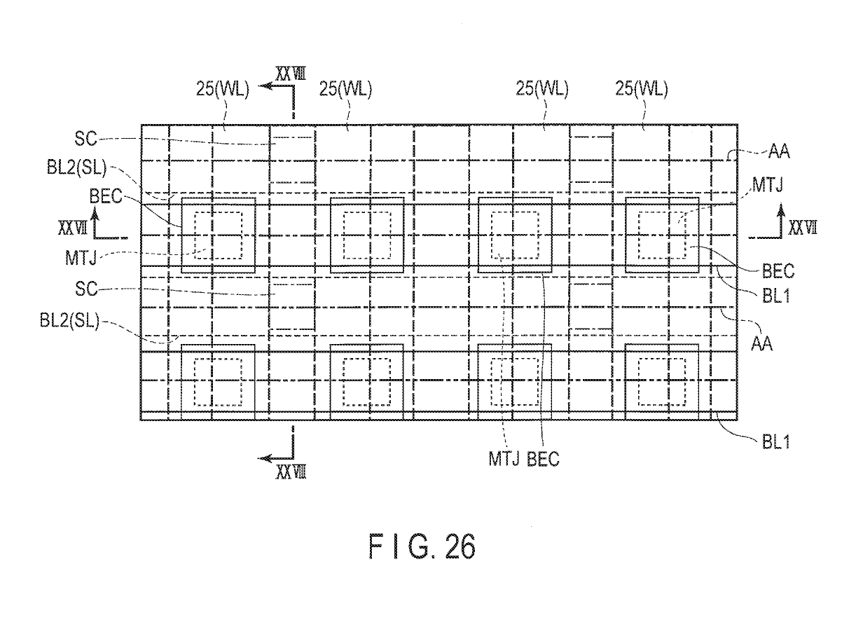

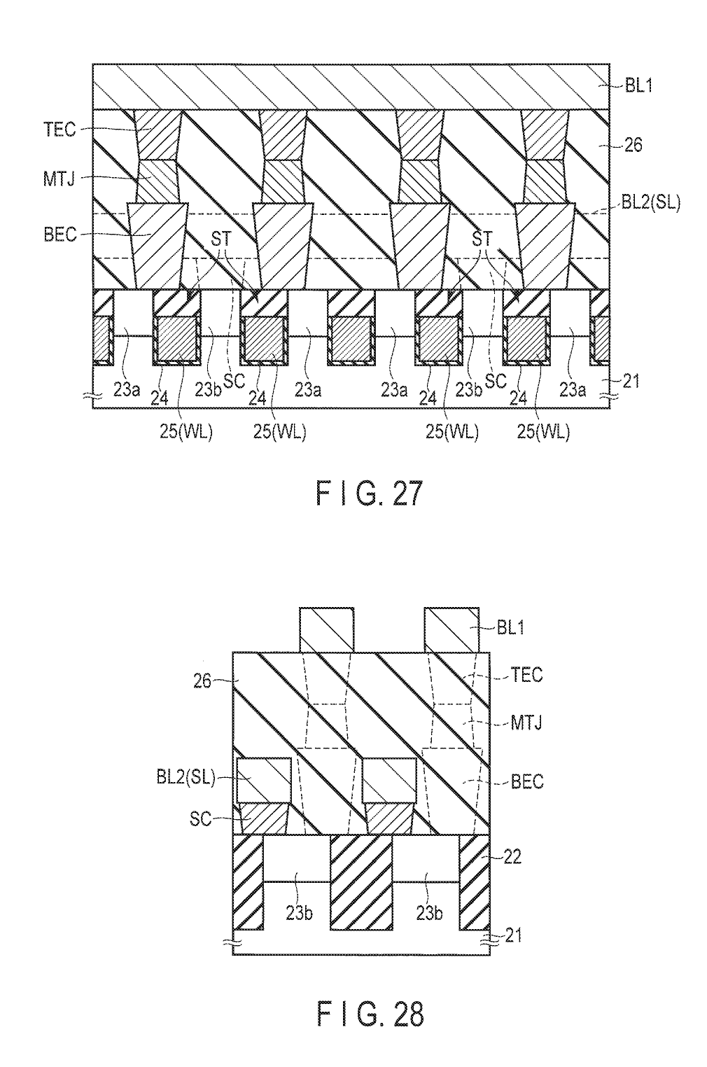

FIG. 26, FIG. 27 and FIG. 28 show memory cells of an MRAM as an application example. FIG. 26 is a plan view of the memory cells of the MRAM. FIG. 27 is a cross-sectional view seen along XXVII-XXVII of FIG. 26. FIG. 28 is a cross-sectional view seen along XXVIII-XXVIII of FIG. 26.

In this example, each memory cell of the magnetic memory comprises a select transistor (for example, FET) ST and a magnetoresistive element MTJ.

The select transistor ST is disposed in an active area AA in a semiconductor substrate 21. The active area AA is surrounded by an element isolation insulating layer 22 in the semiconductor substrate 21. In this example, the element isolation insulating layer 22 has a shallow trench isolation (STI) structure.

Each select transistor ST comprises source/drain diffusion layers 23a and 23b in the semiconductor substrate 21 and a gate insulating layer 24 and a gate electrode (word line) 25 formed in the semiconductor substrate 21 between source/drain diffusion layers 23a and 23b. Each select transistor ST of this example has a buried gate structure in which the gate electrode 25 is buried in the semiconductor substrate 21.

An interlayer insulating layer (for example, oxide silicon layer) 26 covers the select transistors ST. Contact plugs BEC and SC are disposed in the interlayer insulating layer 26. Each contact plug BEC is connected to source/drain diffusion layer 23a and each contact plug SC is connected to source/drain diffusion layer 23b. For example, contact plugs BEC and SC include one of W, Ta, Ru, Ti, TiN, and TaN.

The magnetoresistive elements MTJ are disposed on contact plugs BEC, respectively. A contact plug TEC is disposed on each magnetoresistive element MTJ. For example, contact plugs TEC include one of W, Ta, Ru, Ti, TiN, and TaN.

A bit line BL1 is connected to the magnetoresistive elements MTJ via contact plugs TEC. A bit line BL2 is connected to source/drain diffusion layers 23b via contact plugs SC. For example, bit line BL2 also function as a source line SL to which a ground potential is applied in reading.

### CONCLUSION

As described above, according to the embodiments, the test time can be significantly reduced by restricting a test area, i.e., testing a magnetoresistive element having a characteristic the most distant from a reference characteristic. In addition, by replacing fail bits detected in the test with pass bits by the use of the redundancy technique, the magnetic memory can be manufactured with a high yield. As a result, a magnetic memory of high quality can be manufactured.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A test apparatus comprising:
an interface portion to which a magnetic memory with a memory cell array is connected, the memory cell array including a center area and a peripheral area, the center area being located inside an edge of the memory cell array by a predetermined value; and
a controller controlling a test of the magnetic memory,
wherein the controller is configured to:
execute the test for one of the peripheral area and the center area base on a kind of the test.

2. The test apparatus of claim 1, wherein
the controller executes the test for the peripheral area when a shift of a magnetization reversal characteristic of a magnetoresistive element in the peripheral area is larger than a shift of a magnetization reversal characteristic of a magnetoresistive element in the center area.

3. The test apparatus of claim 2, wherein
the test is one of a 1-retention test and a 1-write error rate test for the peripheral area when the magnetization reversal characteristic of the magnetoresistive element in the peripheral area is shifted to a 1-side, where “1” denotes that the magnetoresistive element is in an antiparallel state.

4. The test apparatus of claim 2, wherein
the test is a read disturb test for the peripheral area when the magnetization reversal characteristic of the magnetoresistive element in the peripheral area is shifted to a 1-side and a read current is provided on a 0-side, where “1” denotes that the magnetoresistive element is in an antiparallel state and “0” denotes that the magnetoresistive element is in a parallel state.

5. The test apparatus of claim 2, wherein
the test is one of a 0-retention test and a 0-write error rate test for the peripheral area when the magnetization reversal characteristic of the magnetoresistive element in the peripheral area is shifted to a 0-side, where “0” denotes that the magnetoresistive element is in a parallel state.

6. The test apparatus of claim 2, wherein
the test is a read disturb test for the peripheral area when the magnetization reversal characteristic of the magnetoresistive element in the peripheral area is shifted to a 0-side and a read current is provided on a 1-side, where “0” denotes that the magnetoresistive element is in a parallel state and “1” denotes that the magnetoresistive element is in an antiparallel state.

7. The test apparatus of claim 1, wherein
the controller executes the test for the center area when a shift of a magnetization reversal characteristic of a magnetoresistive element in the center area is larger than a shift of a magnetization reversal characteristic of a magnetoresistive element in the peripheral area.

8. The test apparatus of claim 7, wherein
the test is one of a 1-retention test and a 1-write error rate test for the center area when the magnetization reversal characteristic of the magnetoresistive element in the center area is shifted to a 1-side, where “1” denotes that the magnetoresistive element is in an antiparallel state.

9. The test apparatus of claim 7, wherein
the test is a read disturb test for the center area when the magnetization reversal characteristic of the magnetoresistive element in the center area is shifted to a 1-side and a read current is provided on a 0-side, where “1” denotes that the magnetoresistive element is in an antiparallel state and “0” denotes that the magnetoresistive element is in a parallel state.

10. The test apparatus of claim 7, wherein
the test is one of a 0-retention test and a 0-write error rate test for the center area when the magnetization reversal characteristic of the magnetoresistive element in the center area is shifted to a 0-side, where “0” denotes that the magnetoresistive element is in a parallel state.

11. The test apparatus of claim 7, wherein
the test is a read disturb test for the center area when the magnetization reversal characteristic of the magnetoresistive element in the center area is shifted to a 0-side and a read current is provided on a 1-side, where “0” denotes that the magnetoresistive element is in a parallel state and “1” denotes that the magnetoresistive element is in an antiparallel state.

12. The test apparatus of claim 1, further comprising:
a magnetic field generating portion applying a magnetic field to the magnetic memory in the test.

13. The test apparatus of claim 1, further comprising:
a temperature control portion controlling a temperature of the magnetic memory in the test.

14. The test apparatus of claim 1, wherein
the memory cell array comprises magnetoresistive elements,
a boundary between the peripheral area and the center area is located inside the edge of the memory cell array by the predetermined value, and
the predetermined value denotes a threshold value of a range of an adjacent area at which a magnetization reversal characteristic of the magnetoresistive elements is equalized.

15. A test method comprising:
dividing a memory cell array of a magnetic memory into a peripheral area and a center area; and
executing a test for one of the peripheral area and the center area base on a kind of the test.

16. The test method of claim 15, wherein
the test is executed for the peripheral area when a shift of a magnetization reversal characteristic of a magnetoresistive element in the peripheral area is larger than a shift of a magnetization reversal characteristic of a magnetoresistive element in the center area.

17. The test method of claim 15, wherein
the test is executed for the center area when a shift of a magnetization reversal characteristic of a magnetoresistive element in the center area is larger than a shift of a magnetization reversal characteristic of a magnetoresistive element in the peripheral area.

18. A method of manufacturing a magnetic memory, the method comprising:
forming a memory cell array including a center area and a peripheral area, the center area and the peripheral area being determined based on stray magnetic fields from magnetoresistive elements in the memory cell array,
wherein the center area includes a valid cell capable of storing data, and
the peripheral area includes a dummy cell not used for storing data.

19. The method of claim 18, wherein
the peripheral area includes the valid cell adjacent to the center area.

20. The method of claim 18, wherein
each of the valid cell and the dummy cell includes a magnetoresistive element.
